(19) United States
(12) Patent Application Publication
(10) Pub. No.: US 2013/0136917 A1
(43) Pub. Date: May 30, 2013

(54) PROCESSES FOR PREPARING DEVICES AND FILMS BASED ON CONDUCTIVE NANOPARTICLES

(71) Applicants: Paul Christopher Dastoor, Callaghan (AU); Warwick Belcher, Callaghan (AU)

(72) Inventors: Paul Christopher Dastoor, Callaghan (AU); Warwick Belcher, Callaghan (AU)

(73) Assignee: NEWCASTLE INNOVATION LIMITED, Callaghan, New South Wales (AU)

(21) Appl. No.: 13/814,405

(22) PCT Filed: Aug. 5, 2011
(86) PCT No.: PCT/AU2011/001001

§ 371 Date: Feb. 5, 2013

(30) Foreign Application Priority Data
Aug. 5, 2010 (AU) 2010903504

(51) Int. Cl. B05D 5/12; H01L 51/00; H01L 51/42

(52) U.S. Cl. CPC B05D 5/12; H01L 51/42; H01L 51/0043; B82Y 30/00
USPC 428/323; 427/58; 427/122; 428/338; 977/932

(57) ABSTRACT

The present invention relates to a process for preparing a device comprising: (i) providing an aqueous emulsion comprising an organic solvent, a surfactant and at least one conductive organic compound; (ii) removal of the organic solvent to provide an aqueous suspension of conductive nanoparticles comprising the at least one conductive organic compound; (iii) depositing the nanoparticles onto a substrate to form a nanoparticle layer; and (iv) annealing the nanoparticle layer.

### TECHNICAL FIELD

The present invention relates to processes for preparing devices and films based on conductive nanoparticles, and to devices made by the process.

### BACKGROUND OF THE INVENTION

It is widely recognised that organic photovoltaics (OPV) will play a major role in the portfolio of renewable energy sources as OPV offers enormous potential as inexpensive coatings capable of generating electricity directly from sunlight. The key competitive advantage of OPV is that the polymer blend materials that comprise the active layer can be printed at high speeds across large areas using roll-to-roll processing techniques thus creating the tantalising vision of coating every roof and other suitable building surface with photovoltaic materials at extremely low cost.

Conventional state-of-the-art OPV devices are fabricated from mixtures of organic donor and acceptor materials dissolved in organic solvents, such as chloroform or chlorobenzene. Depositing such solutions on an appropriate substrate produces an interpenetrating network of electron donors and acceptors. All current fabrication methodologies (for example spin-coating and screen-printing) rely on the thermodynamics of demixing to produce phase segregated regions with the required optimum size of 50 to 100 nm. Although inherently feasible, many aspects of current OPV materials are not well-suited to building large area photovoltaic modules using high speed printing techniques. The reasons for this are twofold. First, tailoring device morphology across large areas is fraught with difficulty since, in general, it is not possible to optimise the phase segregation of a particular polymer mixture using current fabrication approaches. Second, the use of highly volatile and flammable organic solvents presents major problems to the development of a high speed printing line for coating large areas. Clearly, the development of new processing methodology for OPV devices which provides control over the nanoscale morphology whilst simultaneously eliminating or alternatively minimising the need for organic solvents, is urgently required.

The fabrication of nanoparticles of semiconducting polymers dispersed in water is well established and conductive electroactive coatings can be prepared by mixing colloidal (10-100 nm) conducting polymers in a latex base. Landfester et al. (Adv. Mater., 14, 651, (2002)) reported the formation of nanoparticles (50-250 nm) of poly(9,9-dioctylfluorene-co-benzothiadiazole and poly(9,9-dioctylfluorene-co-N,N -bis(4-butylphenyl)-N,Ndiphenyl-1,4-phenylenediamine) semiconducting polymers. Aqueous dispersions of polymer colloids were prepared ultrasonically and spin coated onto surfaces to produce preliminary photovoltaic devices. However, the power conversion efficiency of these devices was extremely low (<0.004%) rendering them useless from a commercial perspective. Subsequently, Snaith et al. (Synth. Met., 147, 105, (2004)) obtained similar efficiencies using an electroplating technique to deposit the nanoparticles as OPV devices. Interestingly, there have been no further reports of aqueous colloid-derived OPV devices since 2004, presumably due to the very low device efficiencies obtained.

Against this background, the present inventors have surprisingly been able to prepare highly efficient OPV devices based on aqueous colloidal particles. Such devices exhibit efficiencies between one and two orders of magnitude better than those previously reported. Even more significantly, these devices are almost twice as efficient as the best corresponding bulk heterojunction devices made from the same materials, and as such exhibit the highest efficiencies reported for these material blends.

### SUMMARY OF THE INVENTION

In a first aspect, the present invention provides a process for preparing a film or device comprising conductive nanoparticles, said process ‘including the step of modulating the surface energy of the nanoparticles.

Modulating the surface energy of the nanoparticles may involve altering the amount of surfactant located at the surface of the nanoparticles.

Altering the amount of surfactant located at the surface of the nanoparticles may be achieved by annealing the nanoparticles when present as a deposited layer on a substrate.

Altering the amount of surfactant located at the surface of the nanoparticles may be achieved prior to depositing the nanoparticles onto a substrate by controlling the amount of surfactant present in an aqueous dispersion comprising the nanoparticles and the surfactant.

Modulating the surface energy of the nanoparticles may involve increasing the surface energy of the nanoparticles or decreasing the surface energy of the nanoparticles.

Increasing the surface energy of the nanoparticles may comprise eliminating, or reducing the amount of, surfactant located at the surface of the nanoparticles.

Eliminating, or reducing the amount of, surfactant located at the surface of the nanoparticles may be achieved by annealing the nanoparticles when present as a deposited layer on a substrate.

Eliminating, or reducing the amount of, surfactant located at the surface of the nanoparticles may be achieved prior to depositing the nanoparticles onto a substrate by controlling the amount of surfactant present in an aqueous dispersion comprising the nanoparticles and the surfactant.

Controlling the amount of surfactant present in the aqueous dispersion may involve dialysis of the aqueous dispersion so as to minimise the amount of surfactant therein.

Modulating the surface energy of the nanoparticles may be achieved by dialysis of an aqueous dispersion comprising the nanoparticles and a surfactant so as to minimise the amount of surfactant therein, and annealing of the nanoparticles once deposited as a nanoparticle layer on a substrate.

The nanoparticles may be core shell nanoparticles.

The nanoparticles may be conductive polymer nanoparticles.

The nanoparticles may be conductive organic nanoparticles.

The nanoparticles may be organic conductive polymer nanoparticles.

The nanoparticles may comprise poly(9,9-dioctylfluorene-2,7-diyl-co-bis-N,N-(4-butylphenyl)-bis-N,N-phenyl-1,4-phenylenediamine) (PFB) and poly(9,9-dioctylfluorene-2,7-diyl-co-benzothiadiazole) (F8BT).

The device may comprise multiple nanoparticle layers, for example two, three, four five, or more layers.

The device may be an electronic device, for example an LED, a transistor or a photovoltaic cell, or a device based on LEDs, transistors or photovoltaic cells, such as a sensor, an array, a memory element or a circuit.

In a second aspect, the present invention provides a process for preparing a film or device comprising conductive nanoparticles, the process including the step of preparing conductive nanoparticles having a mean diameter between about 5 nm and about 200 nm, and a mean domain size between about 2 nm and about 110 nm.

The nanoparticles may have a mean diameter between about 45 nm and about 60 nm, and a mean domain size between about 15 nm and about 30 nm.

The nanoparticles may have a mean particle diameter of about 50 nm and a mean domain size between about 20 nm and about 25 nm.

The nanoparticles may be core shell nanoparticles.

The nanoparticles may be conductive polymer nanoparticles.

The nanoparticles may be conductive organic nanoparticles.

The nanoparticles may be organic conductive polymer nanoparticles.

The nanoparticles may comprise PFB and F8BT.

The device may be an electronic device, for example an LED, a transistor or a photovoltaic cell, or a device based on LEDs, transistors or photovoltaic cells, such as a sensor, an array, a memory element or a circuit.

The process of the second aspect may include the step of modulating the surface energy of the nanoparticles according to the process described in the first aspect.

In a third aspect, the present invention provides a process for preparing a device comprising:

(i) providing an aqueous emulsion comprising an organic solvent, a surfactant and at least one conductive organic compound;

(ii) removal of the organic solvent to provide an aqueous suspension of conductive nanoparticles comprising the at least one conductive organic compound;

(iii) depositing the nanoparticles onto a substrate to form a nanoparticle layer; and

(iv) annealing the nanoparticle layer.

The organic solvent may be a halogenated solvent, for example a chlorinated solvent.

The ratio of water to organic solvent in the aqueous emulsion may be between about 2:1 arid about 6:1, or between about 3:1 and about 6:1, or between about 4:1 and about 6:1, or alternatively about 4:1.

The surfactant may be sodium dodecylsulfate (SDS).

The process may further comprise dialysis of the aqueous suspension of nanoparticles so as to minimise the amount of surfactant therein.

Dialysis may be performed until the surface tension of a filtrate is less than about 50 mN/m.

The nanoparticles may have a mean diameter in the range of about 5 nm and about 200 nm, or in the range of about 35 nm and about 70 nm, or in the range of about 45 nm and about 60 nm, or about 50 nm.

The mean domain size of the nanoparticles may be in the range of about 2 nm and about 110 nm, or in the range of about 15 nm and about 30 nm, or in the range of about 15 nm and about 25 nm, or in the range of about 20 nm and about 25 nm.

In one embodiment, the nanoparticles have a mean diameter in the range of about 5 nm and 200 nm, and a mean domain size in the range of about 2 nm and 110 nm.

In an alternative embodiment, the nanoparticles have a mean diameter in the range of about 20 nm and about 100 nm, and a mean domain size in the range of about 10 nm and about 50 nm.

In an alternative embodiment, the nanoparticles have a mean diameter in the range of about 45 nm and about 60 nm, and a mean domain size in the range of about 15 nm and about 30 nm.

In another embodiment, the nanoparticles have a mean diameter in the range of about 45 nm and about 55 nm, and a mean domain size in the range of about 20 nm and about 25 nm.

The nanoparticles may comprise at least one conductive organic compound selected from the group consisting of porphyrins, phthalocyanins, polyacetylenes, fullerenes, polyparaphenylenes, polyphenylenevinylenes, polyfluorenes, polycarbazoles, polythiophenes, polypyrroles, polypyridines, polypyridinevinylenes, polyarylvinylenes, poly (p-phenylmethylvinylenes), including derivatives and co-polymers thereof.

In one embodiment the nanoparticles comprise at least one conductive organic compound selected from the group consisting of: poly(9,9-dioctylfluorene-2,7-diyl-co-bis-N,N-(4-butylphenyl)-bis-N,N-phenyl-1,4-phenylenediamine), poly(9,9-dioctylfluorene-2,7-diyl-co-benzothiadiazole), poly-3-hexylthiophene, (6,6)-phenyl-C₆₁-butyric acid methyl ester and poly(2-methoxy-5-(2′-ethyl-hexyloxy)-1,4-phenylene vinylene).

In another embodiment the nanoparticles comprise the following conductive organic compounds: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

In a further embodiment the nanoparticles comprise a conductive organic polymer compound, which may be selected from the group consisting of: polyacetylenes, polyparaphenylenes, polyphenylenevinylenes, polyfluorenes, polycarbazoles, polythiophenes, polypyrroles, polypyridines, polypyridinevinylenes, polyarylvinylenes, poly (p-phenylmethylvinylenes), including derivatives and co-polymers thereof.

The aqueous emulsion may comprise at least two conductive organic polymer compounds. In one embodiment, the conductive organic polymer compounds are PFB and F8BT.

Step (iv) may be carried out by heating the nanoparticle layer.

The process may comprise repeating step (iii) so as to provide multiple nanoparticle layers.

Step (iii) may be repeated once, twice, three, four, five or more times so as to provide multiple nanoparticle layers.

Step (iii) may be repeated two, three or four times.

Step (iii) may be repeated four times so as to provide five nanoparticle layers.

Following step (iii), and each repetition thereof, the nanoparticle layer(s) may be dried.

Following step (iii), and each repetition thereof, the nanoparticle layer(s) may be dried at a temperature between about 50° C. and 150° C.

The nanoparticle layer(s) may be dried by heating at a temperature between about 30° C. and 180° C. for a period of time between about 30 seconds and 30 minutes.

The nanoparticle layer(s) may be dried by heating at a temperature between about 60° C. and 150° C. for a period of time between 2 and 20 minutes.

Step (iv) may be carried out by heating the nanoparticle layer(s) at a temperature between about 130° C. and 150° C.

Step (iv) may be carried out by heating the nanoparticle layer(s) at a temperature between about 70° C. and 180° C. for a period of time between about 30 seconds and 30 minutes.

Step (iv) may be carried out by heating the nanoparticle layer(s) at a temperature between about 120° C. and 150° C. for a period of time between about 30 seconds and 5 minutes.

The thickness of the nanoparticle layer(s) may be between about 100 nm and about 500 nm, or between about 50 nm and about 350 nm, or between about 100 nm and about 350 nm.

In a fourth aspect, the present invention provides a process for preparing a film or device comprising conductive nanoparticles, said process including the step of removing surfactant located at the surface of the nanoparticles.

The nanoparticles may be conductive polymer nanoparticles.

The nanoparticles may be organic conductive polymer nanoparticles.

The surface may be the outermost surface of the nanoparticles.

The surfactant may be removed by the methods described in the first aspect. The nanoparticles may be nanoparticles as defined herein.

In a fifth aspect, the present invention provides a device or film whenever prepared by the process of the first, second, third or fourth aspects.

In a sixth aspect, the present invention provides a device comprising at least one nanoparticle layer, the nanoparticles comprising at least one conductive organic compound and having a mean diameter between about 5 nm and 200 nm and a mean domain size between about 2 nm and 110 nm, wherein the surface of the nanoparticles is free, or substantially free, of surfactant.

The surface may be the outermost surface.

The nanoparticles may have a mean diameter between about 45 nm and 60 nm and a mean domain size between about 15 nm and 30 nm.

The nanoparticles may comprise at least one conductive organic polymer compound.

The nanoparticles may comprise: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

The nanoparticles may have a surface energy between about 30 and about 40 J/m³.

The device may comprise five nanoparticle layers.

The device may be an electronic device.

These and other aspects of the invention will become evident from the description and claims which follow.

### BRIEF DESCRIPTION OF THE FIGURES

A preferred embodiment of the present invention will now be described, by way of example only, with reference to the accompanying drawings wherein:

FIG. 1: a). Chemical structure of the polymer poly(9,9-dioctylfluorene-co-benzothiadiazole (F8BT). b). Chemical structure of the polymer poly(9,9-dioctylfluorene-co-N,N-bis(4-butylphenyl)-N,Ndiphenyl-1,4-phenylenediamine) (PFB). c). Dynamic light scattering plot showing typical particle size distribution. d). Transmission electron micrograph of the PFB:F8BT nanoparticles.

FIG. 2: Atomic force micrographs of the sequential deposition of the multilayered PFB:F8BT nanoparticle device structure. a: Clean ITO substrate, b: PEDOT:PSS layer, c: PEDOT:PSS post-annealed layer. d: PFB:F8BT layer 1, e: PFB:F8BT layer 2, f: PFB:F8BT layer 3, g: PFB:F8BT layer 4, h: PFB:F8BT layer 5, is PFB:F8BT post-annealed layer 5. The scale bar is 2 μm and is the same for all of the images. Also shown are the rms roughness values for the nanoparticulate films.

FIG. 3: a). Variation of film thickness with the number of deposited nanoparticulate layers for unannealed (open circles) and annealed films (closed circles). b). UV-Vis spectra for PFB-F8BT unannealed (dashed line) and annealed (solid line) nanoparticulate films consisting of 1 to 5 layers. Also shown (dotted line) is the UV-Vis spectra for a standard bulk heterojunction PFB-F8BT film with an active layer thickness of 120 nm. c). Optical micrographs for the unannealed (upper row) and annealed (lower row) for nanoparticulate films consisting of one to five layers. The scale bar is 5 microns in each micrograph.

FIG. 4: a). STXM maps of the PFB (top), F8BT (middle) and SDS (bottom) composition of a single unannealed PFB:F8BT nanoparticle deposited onto a silicon nitride window. The colour bar is scaled such that light colours correspond to higher component concentrations. The scale bar corresponds to 50 nm and is the same in each image. b). Contact angle measurements for a droplet of blended PFB:F8BT nanoparticle dispersions on a PFB:F8BT nanoparticle film as a function of the film drying temperature. Also shown are contact angle values for a droplet of blended PFB:F8BT nanoparticles on a pure F8BT (upper solid line) and pure PFB (lower dashed line) spin cast film at room temperature as well as representative blended PFB:F8BT nanoparticle dispersion sessile droplet images taken at increasing temperatures. c). XPS S 2p spectra for PFB:F8BT unannealed nanoparticles and nanoparticles annealed at 100, 110, 120, 130, 140 and 170° C.

FIG. 5: a). Differential scanning calorimetry (DSC) traces for pure SDS. b). DSC traces for blended PFB:F8BT nanoparticles. Traces of sequential temperature ramps to increasingly higher maximum temperature settings are shown. A: Ramp to 50° C., B: Ramp to 75° C., C: Ramp to 100° C., D: Ramp to 125° C., E: Ramp to 150° C., F: Ramp to 175° C. The dashed line shows the position of the irreversible exothermic transition that occurs at 110° C. The dotted lines highlight the positions of the reversible exothermic transition that occurs at 89° C. in pure SDS and 79° C. in the PFB:F8BT nanoparticles. c). Thermal gravimetric analysis PFB:F8BT nanoparticles. d). X-ray reflectometry (XRR) data for unannealed (upper dotted blue line) and annealed (lower dotted red line) PFB:F8BT nanoparticle films. Also shown are the model fits (solid black lines) for uniform scattering layers of thickness 74.5 nm and 62.6 nm for the unannealed and annealed XRR data respectively. e). XRR data for the low q_{z} region. f. AFM image of a cluster of typical SDS crystallites on an unannealed 5 layer PFB:F8BT nanoparticulate film.

### DEFINITIONS

Throughout this specification and the claims which follow, unless the context requires otherwise, the word “comprise”, and variations such as “comprises” or “comprising”, will be understood to imply the inclusion of a stated integer or step or group of integers or steps but not the exclusion of any other integer or step or group of integers or steps.

The articles “a” and “an” are used herein to refer to one or to more than one (i.e., to at least one) of the grammatical object of the article. By way of example, “an element” means one element or more than one element.

In the context of this specification, the term “about” is understood to refer to a range of numbers that a person of skill in the art would consider equivalent to the recited value in the context of achieving the same function or result.

### DETAILED DESCRIPTION OF THE INVENTION

The present inventors have surprisingly discovered that the performance of nanoparticulate devices relative to bulk heterojunction devices can be improved by modulating the surface energy of the constituent nanoparticles. Accordingly, in a first aspect the present invention provides a process for preparing a film or device comprising conductive nanoparticles, said process including the step of modulating the surface energy of the nanoparticles.

Modulating the surface energy of the nanoparticles may involve altering the amount of surfactant located at the surface of the nanoparticles.

The step of modulating the surface energy of the nanoparticles may involve a step which either increases or decreases the surface energy of the nanoparticles.

In one embodiment, increasing the surface energy of the nanoparticles comprises eliminating, or reducing the amount of, surfactant located at the surface of the nanoparticles. Without wishing to be bound by theory, the inventors believe that the elimination of, or reduction in the amount of, surfactant located at the surface of the nanoparticles results in a thinner and denser nanoparticle film structure which provides improved inter-particle connectivity that is required for charge transport within the device. Eliminating, or reducing the amount of, surfactant located at the surface of the nanoparticles may be achieved by a number of methods. One method involves annealing the nanoparticles. Annealing may be performed following deposition of the nanoparticles on a substrate to form a nanoparticle layer (or in other words, a film). Again without wishing to be bound by theory, the inventors believe that upon annealing, the surfactant becomes mobile and is no longer located at the surface of the nanoparticles, but rather has become incorporated into the bulk. This incorporation of surfactant is likely facilitated by an irreversible chain-melting transition that occurs just below the annealing temperature.

Annealing may be achieved by heating the nanoparticles at a temperature between about 30° C. and 180° C., or between about 50° C. and 180° C., or between about 60° C. and 180° C., or between about 70° C. and 180° C., or between about 80° C. and 180° C., or between about 90° C. and 180° C., or between about 100° C. and 180° C., or between about 110° C. and 170° C., or between about 120° C. and 160° C., or between about 130° C. and 150° C., or between about 135° C. and 145° C. The heating may be performed for a period of time between about 30 seconds and 30 minutes, or between about 30 seconds and 20 minutes, or between about 1 minute and 20 minutes, or between about 1 minute and 15 minutes, or between about 1 minute and 10 minutes, or between about 1 minute and 5 minutes, or about 4 minutes. In one embodiment, annealing may be achieved by heating the nanoparticles at about 140° C. for about 4 minutes. Annealing may be performed on a hotplate and may be performed under an inert atmosphere.

The preparation of nanoparticles for use in organic nanoparticulate devices typically involves preparing an emulsion composition comprising an aqueous solvent, an organic solvent, a surfactant and one or more conductive polymer compounds. Following agitation and removal of the organic solvent, an aqueous dispersion of polymer nanoparticles is obtained, wherein the aqueous phase comprises the surfactant.

Eliminating, or reducing the amount of, surfactant located at the surface of the nanoparticles may therefore alternatively (or in addition) be achieved prior to depositing the nanoparticles onto a substrate by controlling the amount of surfactant present in an aqueous dispersion comprising the nanoparticles and the surfactant. This may be achieved, for example, by dialysis of the aqueous dispersion so as to minimise the amount of surfactant therein.

In one embodiment, the process of the first aspect comprises the following steps: dialysis of an aqueous dispersion comprising conductive nanoparticles and a surfactant so as to minimise the amount of surfactant therein, and annealing of the nanoparticles once deposited as a nanoparticle layer on a substrate.

The present inventors have further discovered that the performance of nanoparticulate devices relative to bulk heterojunction devices can be improved by controlling the mean diameter of the particles and the size of the donor and acceptor domains. Accordingly, in a second aspect, the present invention provides a process for preparing a film or device comprising conductive nanoparticles, the process including the step of preparing conductive nanoparticles having a mean diameter between about 5 nm and about 200 nm, and a mean domain size between about 2 nm and about 110 nm. The nanoparticles may be core shell nanoparticles.)

The nanoparticles of the first and second aspects, and also the third, fourth and sixth aspects may have a mean diameter between about 5 nm and about 200 nm, or between about 5 nm and about 180 nm, or between about 5 nm and about 160 nm, or between about 5 nm and about 140 nm, or between about 5 nm and about 120 nm, or between about 5 nm and about 100 nm, or between about 5 nm and about 80 nm, or between about 5 nm and about 75 nm, or between about 10 nm and about 190 nm, or between about 15 nm and about 180 nm, or between about 20 nm and about 170 nm, or between about 20 nm and about 160 nm, or between about 25 nm and about 150 run, or between about 30 nm and about 140 nm, or between about 30 nm and about 130 nm, or between about 30 nm and about 120 nm, or between about 30 nm and about 110 nm, or between about 30 nm and about 100 nm, or between about 30 nm and about 90 nm, or between about 30 nm and about 80 nm, or between about 30 nm and about 75 nm, or between about 40 nm and about 70 nm, or between about 40 nm and about 60 nm, or between about 35 nm and about 70 nm, or between about 45 nm and about 60 nm, or between about 45 nm and 55 nm, or between about 20 nm and about 200 nm, or between about 30 nm and about 200 nm, or between about 30 nm and about 190 nm, or between about 40 nm and 180 nm.

The nanoparticles of the first and second aspects, and also the third, fourth and sixth aspects may have a mean domain size between about 2 nm and about 110 nm, or between about 2 nm and about 100 nm, or between about 2 nm and about 90 nm, or between about 2 nm and about 75 nm, or between about 2 nm and about 65 nm, or between about 2 nm and about 50 nm, or between about 2 nm and about 45 nm, or between about 2 nm and about 40 nm, or between about 5 nm and about 100 nm, or between about 5 nm and about 90 nm, or between about 10 nm and about 85 nm, or between about 10 nm and about 75 nm, or between about 15 nm and about 80 nm, or between about 15 nm and about 75 nm, or between about 15 nm and about 70 nm, or between about 15 nm and about 60 nm, or between about 15 nm and about 60 nm, or between about 15 nm and about 50 nm, or between about 15 nm and about 40 nm, or between about 15 nm and about 35 nm, or between about 20 nm and about 35 nm, or between about 15 nm and about 35 nm, or between about 20 nm and about 35 nm, or between about 20 nm and 35 nm, or between about 10 nm and about 110 nm, or between about 15 nm and about 100 nm, or between about 15 nm and about 95 nm, or between about 20 nm and 100 nm.

In embodiments of the first, second, third, fourth and sixth aspects, the nanoparticles have a mean diameter between about 5 nm and about 200 nm, and a mean domain size between about 2 nm and about 110 nm, or the nanoparticles have a mean diameter between about 5 nm and about 150 nm, and a mean domain size between about 2 nm and about 75 nm, or the nanoparticles have a mean diameter between about 15 nm and about 120 nm, and a mean domain size between about 5 nm and about 60 nm, or the nanoparticles have a mean diameter between about 25 nm and about 100 nm, and a mean domain size between about 10 nm and about 50 nm, or the nanoparticles have a mean diameter between about 30 nm and about 90 nm, and a mean domain size between about 15 nm and about 45 nm, or the nanoparticles have a mean diameter between about 40 nm and about 80 nm, and a mean domain size between about 20 nm and about 45 nm, or the nanoparticles have a mean diameter between about 45 nm and about 60 nm, and a mean domain size between about 15 nm and about 30 nm.

In one embodiment, the nanoparticles have a mean diameter of about 50 nm and a mean domain size between about 20 nm to 25 nm.

When preparing nanoparticles using emulsion techniques, the particle diameter and domain size may be controlled by varying the nature and amount of the surfactant present (an increase in the concentration of the surfactant results in a decrease in particle diameter), and/or by the application of shear force (for example ultrasound or high pressure homogenisation). The use of shear force allows the preparation of nanoparticles in which up to 98% of the nanoparticles have a diameter which differs from the mean diameter of all nanoparticles by not more than 10%. Particle diameter and domain size may also be controlled by annealing films comprising the nanoparticles as described above in connection with the first aspect.

In the first and second aspects, the nanoparticles may comprise PFB and F8BT. However, the processes of the first and second aspects are compatible with nanoparticles which comprise any conductive compounds, for example conductive organic compounds, including, but not limited to: polyacetylenes, porphyrins, phthalocyanins, fullerenes, polyparaphenylenes, polyphenylenevinylenes, polyfluorenes, polythiophenes, polypyrroles, polypyridines, polycarbazoles, polypyridinevinylenes, polyarylvinylenes, poly (p-phenylmethylvinylenes), including derivatives and co-polymers thereof.

In one embodiment, the nanoparticles of the first and second aspects comprise conductive polymer compounds, for example conductive organic polymer compounds, including, but not limited to: polyacetylenes, polyparaphenylenes, polyphenylenevinylenes, polyfluorenes, polythiophenes, polypyrroles, polypyridines, polycarbazoles, polypyridinevinylenes, polyarylvinylenes and poly (p-phenylmethylvinylenes), including derivatives and co-polymers thereof.

In one embodiment of the first and second aspects, the nanoparticles comprise at least one conductive organic compound selected from the group consisting of PFB, F8BT, poly-3-hexylthiophene (P3HT), (6,6)-phenyl-C₆₁-butyric acid methyl ester (PCBM) andpoly(2-methoxy-5-(2′-ethyl-hexyloxy)-1,4-phenylene vinylene) (MEH-PPV).

The process of the second aspect may include the step of increasing the surface energy of the nanoparticles according to the process described in the first aspect. Accordingly, in one embodiment the present invention provides a process comprising the following steps: preparing conductive nanoparticles having a mean diameter between about 5 nm and about 200 nm, and a mean domain size between about 2 nm and about 110 nm, dialysis of an aqueous dispersion comprising the conductive nanoparticles and a surfactant so as to minimise the amount of surfactant therein, and annealing of the conductive nanoparticles once deposited as a film on a substrate. In this embodiment, the nanoparticles may be core shell nanoparticles, and may comprise PFB and F8BT. The nanoparticles may alternatively comprise any conductive compounds, such as those described above in connection with the first and second aspects. The device or film may comprise multiple layers, for example two, three, four, five or more layers. Dialysis may be performed until the surface tension of the filtrate is less than about 200 mN/m, or less than about 100 mN/m, or less than about 50 mN/m, or less than about 40 nm/m, or about 38 mN/m. The nanoparticles may have a mean diameter between about 45 nm and about 60 nm and a mean domain size between about 15 nm and about 30 nm.

In a third aspect, the invention relates to a process for preparing a device comprising the following steps:

(i) providing an aqueous emulsion comprising an organic solvent, a surfactant and at least one conductive organic compound;

(ii) removal of the organic solvent to provide an aqueous suspension of conductive nanoparticles comprising the at least one conductive organic compound;

(iii) depositing the nanoparticles onto a substrate to form a nanoparticle layer; and

(iv) annealing the nanoparticle layer.

Organic solvents suitable for use in the process include any organic solvents which are capable of dissolving, or partially dissolving, the at least one conductive organic compound. Examples of suitable organic solvents include, but are not limited to: alcohols, ethers, ketones, glycol ethers, hydrocarbons and halogenated hydrocarbons. In one embodiment, the solvent is a halogenated solvent, such as chloroform, dichloroethane, dichloromethane or chlorobenzene.

The surfactant may be any suitable compound comprising at least one hydrophilic group and at least one hydrophobic group. Suitable surfactants include, but are not limited to: alkyl benzenesulfonates, alkyl sulfates, alkyl sulfonates, fatty alcohol sulfates, alkyl phosphates and alkyl ether phosphates. In one embodiment, the surfactant is sodium dodecyl sulfate.

The process preferably comprises agitation of the aqueous emulsion of step (i) so as to produce a mini- or micro-emulsion. Agitation may be achieved by methods well known to those skilled in the art, including the use of shear force, for example ultrasound or high pressure homogenisation.

The process may further comprise dialysis of the aqueous suspension of nanoparticles so as to minimise the amount of surfactant therein. In one embodiment, dialysis is performed by ultracentrifuge. Dialysis may be performed until the surface tension of the filtrate is less than about 200 mN/m, or less than about 100 mN/m, or less than about 50 mN/m, or less than about 40 mN/m, or about 38mN/m.

The nanoparticles may have mean diameters and mean domain sizes as defined above.

In one embodiment, the nanoparticles have a mean diameter in the range of about 45 nm to about 60 nm, or in the range of about 45 nm to about 55 nm. The mean domain size of the nanoparticles may be in the range of about 15 nm and about 30 nm, or in the range of about 20 nm and about 25 nm. In one embodiment, the nanoparticles have a mean diameter of about 50 nm and a mean domain size between about 20 nm to 25 nm.

The at least one conductive organic compound may be as defined above in connection with the first and second aspects.

The aqueous emulsion may comprise at least two conductive organic polymer compounds. In one embodiment, the at least two conductive organic polymer compounds are PFB and F8BT. The weight ratio of PFB:F8BT may be about 1:1.

Step (iv) of the process may be carried out by heating the nanoparticle layer as described above in connection with the first aspect.

In one embodiment, the process comprises repeating step (iii) so as to provide to multiple nanoparticle layers. Step (iii) may be repeated once, twice, three, four, five or more times so as to provide multiple nanoparticle layers. In one embodiment, step (iii) is repeated four times so as to provide a device having five nanoparticle layers. The inventors have found that a five layer device prepared in accordance with the process of the invention provides unprecedented power conversion efficiency (under AM I.5 illumination) of 0.39% (see Example below).

Following step (iii) and each repetition thereof, the nanoparticle layer(s) may be dried. The nanoparticle layer(s) may be dried by heating at a temperature between about 30° C. and 180° C., or between about 40° C. and 170° C., or between about 50° C. and 150° C., or between about 60° C. and 150° C. The heating may be continued for a period of time between about 30 seconds and 30 minutes, or between about 1 minute and 20 minutes or between about 2 minutes and 20 minutes.

Following step (iii) and each repetition thereof, optionally with the exception of the final nanoparticle layer, the nanoparticle layer(s) may be dried at a temperature between about 30° C. and 120° C., or between about 40° C. and 110° C., or between about 50° C. and 100° C., or between about 50° C. and 90° C., or between about 50° C. and 80° C., or between about 60° C. and 80° C., or between about 65° C. and 75° C. The heating may be continued for a period of time between about 30 seconds and 30 minutes, or between about 30 seconds and 20 minutes, or between about 1 minute and 20 minutes, or between about 2 minutes and 20 minutes, or between about 4 minutes and 20 minutes, or between about 5 minutes and 20 minutes, or between about 10 minutes and 20 minutes, or between about 12 minutes and 16 minutes, or about 15 minutes. In one embodiment, following step (iii), and/or each repetition thereof, the nanoparticle layer is dried at a temperature between about 65° C. and 75° C. for a period of time between about 12 and 16 minutes.

Following deposition of the final nanoparticle layer in step (iii) the nanoparticle layer(s) may be dried by heating at a temperature between about 40° C. and 180° C., or between about 60° C. and 180° C., or between about 70° C. and 170° C., or between about 90° C. and 170° C., or between about 100° C. and 160° C., or between about 120° C. and 160° C., or between about 130° C. and 150° C. or between about 135° C. and 145° C., or about 140° C. The heating may be continued for a period of time between about 30 seconds and 30 minutes, or between about 30 seconds and 20 minutes, or between about 1 minute and 10 minutes or between about 2 minutes and 15 minutes, or between about 2 minutes and 10 minutes, or between about 2 minutes and 5 minutes, or about 4 minutes. In one in embodiment, the final nanoparticle layer may be dried at a temperature between about 135° C. and 145° C. for a period of time between about 2 minutes and 5 minutes.

Step (iii) may be performed by methods well known to those skilled in the art including, but not limited to: electroplating, vapour phase deposition, spin coating, screen printing, inkjet printing, slot-dye printing, spray coating, draw bar coating or derived coating/printing techniques thereof, painting, gravure, roller and embossing.

Step (iv) may be carried out by heating the nanoparticle layer(s) at a temperature between about 70° C. and 180° C., or between about 80° C. and 170° C., or between about 80° C. and 160° C., or between about 90° C. and 160° C., or between about 100° C. and 160° C., or between about 110° C. and 160° C., or between about 120° C. and 160° C., or between about 130° C. and 150° C., or between about 135° C. and 145° C. The heating may be continued for a period of time between about 30 seconds and 30 minutes, or between about 30 seconds and 20 minutes, or between about 1 minute and 15 minutes or between about 2 minutes and 15 minutes, or between about 2 minutes and 10 minutes, or between about 2 minutes and 6 minutes, or about 4 minutes. In one embodiment, step (iv) may be carried out by heating the nanoparticle layer at a temperature between about 135° C. and 145° C. for a period of time between about 2 minutes and 10 minutes.

Step (iv) may be carried out following application of an electrode or electrodes to the device.

The thickness of the nanoparticle layer(s) may be between about 100 nm and about 500 nm, or between about 50 nm and about 350 nm, or between about 100 nm and about 350 nm.

The substrate may be PEDOT:PSS on ITO, glass on ITO, ITO on a flexible substrate, conducting transparent coatings on transparent substrates, carbon, graphene, carbon nanotubes, a thin metal layer, or any other suitable substrate known to those skilled in the art. In one embodiment, the substrate is a PEDOT:PSS layer on ITO. The process may further comprise annealing the PEDOT:PSS layer following coating on the ITO. The PEDOT:PSS layer may be annealed by heating according to the annealing conditions described herein, for example by heating at a temperature between about 100° C. and 160° C. for a period of time between about 1 minute and 1 hour.

In an embodiment of the third aspect, the invention provides a process for preparing a device comprising the following steps:

(i) providing an aqueous emulsion comprising an organic solvent, a surfactant and at least one conductive organic compound;

(ii) removal of the organic solvent to provide an aqueous suspension of conductive nanoparticles comprising the at least one conductive organic compound;

(iii) depositing the nanoparticles onto a substrate to form a nanoparticle layer;

(iv) repeating step (iii) three times so as to provide four nanoparticle layers;

(v) following performance of step (iii) and each repetition thereof, drying the nanoparticle layer(s);

(vi) repeating step (iii) so as to provide five nanoparticle layers;

(vii) drying the nanoparticle layer(s) following step (vi);

(viii) annealing the nanoparticle layer(s).

In this embodiment:

The conductive organic compound may be a conductive organic polymer compound.

Step (v) may be performed by heating at a temperature between about 40° C. and 100° C., or at a temperature between about 50° C. and 90° C., or at a temperature between about 60° C. and 80° C.

Step (vii) may be performed by heating at a temperature between about 100° C. and 160° C., or at a temperature between about 120° C. and 160° C., or at a temperature between 130° C. and 150° C.

Step (viii) may be performed by heating at temperature between about 100° C. and 160° C., or at a temperature between about 130° C. and 150° C.

Step (v) may be performed by heating at a temperature between about 50° C. and 90° C. for a period of time between about 10 and 20 minutes.

Step (vii) may be performed by heating at a temperature between about 120° C. and 160° C. for a period of time between about 10 and 20 minutes.

Step (viii) may be performed by heating at temperature between about 130° C. and 150° C. for a period of time between about 2 minutes and 10 minutes.

The nanoparticles may comprise the following conductive organic polymer compounds: PFB and F8BT, and the nanoparticles may have a mean diameter between about 45 nm and about 60 nm, and a mean domain size between about 15 nm and about 25 nm. The nanoparticles may be core shell nanoparticles. The device may be a photovoltaic device. The process may further comprise dialysis of the aqueous suspension of nanoparticles so as to minimise the amount of surfactant therein. Dialysis may be performed until the surface tension of the filtrate is less than about 200 mN/m, or less than about 100 mN/m, or less than about 50 mN/m, or less than about 40 mN/m, or about 38 mN/m. The surfactant may be SDS. The substrate may be PEDOT:PSS on ITO.

In another embodiment of the third aspect, the invention provides a process for preparing a device comprising the following steps:

(i) providing an aqueous emulsion comprising an organic solvent, a surfactant and at least two conductive organic compounds;

(ii) agitation of the aqueous emulsion in step (i) so as to produce a mini- or micro-emulsion.

(iii) removal of the organic solvent to provide an aqueous suspension of conductive nanoparticles;

(iv) dialysis of the aqueous suspension of nanoparticles so as to minimise the amount of surfactant therein;

(v) depositing the nanoparticles obtained following step (iv) onto a substrate to form a first nanoparticle layer;

(vi) optionally drying the nanoparticle layer obtained following step (v);

(vii) depositing the nanoparticles obtained following step (iv) onto the first nanoparticle layer obtained following step (vi) so as to form a second nanoparticle layer;

(viii) optionally drying the nanoparticle layer(s) obtained following step (vii);

(ix) depositing the nanoparticles obtained following step (iv) onto the second nanoparticle layer obtained following step (viii) so as to form a third nanoparticle layer;

(x) optionally drying the nanoparticle layer(s) obtained following step (ix);

(xi) depositing the nanoparticles obtained following step (iv) onto the third nanoparticle layer obtained following step (x) so as to form a fourth nanoparticle layer;

(xii) optionally drying the nanoparticle layer(s) obtained following step (xi);

(xiii) depositing the nanoparticles obtained following step (iv) onto the fourth nanoparticle layer obtained following step (xii) so as to form a fifth nanoparticle layer;

(xiv) optionally drying the nanoparticle layer(s) obtained following step (xiii);

(xv) annealing the nanoparticle layer(s) obtained following step (xiv).

In this embodiment:

The at least two conductive organic compounds may be conductive organic polymer compounds.

Drying the nanoparticle layer(s) may comprise heating at a temperature between about 50° C. and 90° C.

Drying the nanoparticle layer(s) may comprise heating at a temperature between about 60° C. and 80° C.

Drying the nanoparticle layer(s) in step (xiv) may be performed by heating the nanoparticle layers at a temperature between about 130° C. and 150° C.

Drying the nanoparticle layer(s) may comprise heating at a temperature between about 50° C. and 90° C., for a period of time between about 10 minutes and 20 minutes.

Drying the nanoparticle layer(s) may comprise heating at a temperature between about 60° C. and 80° C., for a period of time between about 10 minutes and 20 minutes.

Drying the nanoparticle layer(s) in step (xiv) may be performed by heating the nanoparticle layers at a temperature between about 130° C. and 150° C. for a period of time between about 1 minute and 6 minutes.

Annealing the nanoparticle layer(s) may comprise heating at temperature between about 130° C. and 150° C.

Annealing the nanoparticle layer(s) may comprise heating at temperature between about 130° C. and 150° C. for a period of time between about 2 minutes and 10 minutes.

The at least two conductive organic polymer compounds may be PFB and F8BT, and the nanoparticles may have a mean diameter between about 45 nm and about 60 nm, and a mean domain size between about 15 nm and about 25 nm. The nanoparticles may be core shell nanoparticles. The device may be a photovoltaic device. Dialysis may be performed until the surface tension of the filtrate is less than about 200 mN/m, or less than about 100 mN/m, or less than about 50 mN/m, or less than about 40 mN/m, or about 38mN/m. The surfactant may be SDS. The substrate may be PEDOT:PSS on ITO.

In a sixth aspect, the invention relates to a device comprising at least one nanoparticle layer, the nanoparticles comprising at least one conductive organic compound and having a mean diameter between about 5 nm and 200 nm and a mean domain size between about 2 nm and 110 nm, wherein the surface of the nanoparticles is free, or substantially free, of surfactant.

In this context, the term “substantially free” means that the surface composition of the nanoparticles comprises less than 10%, or less than 9%, or less than 8%, or less than 7%, or less than 6%, or less than 5%, or less than 4%, or less than 3%, or less than 2%, or less than 1%, or less than 0.5%, or less than 0.1%, or less than 0.01%, or less than 0.001%, surfactant by weight. The surface may be the outermost surface of the nanoparticles.

The nanoparticles may comprise any conductive organic compound(s), such as those described above in connection with the first, second and third aspects. In one embodiment, the nanoparticles may comprise at least one conductive organic polymer compound. The nanoparticles may have a mean diameter and a mean domain size as described above in connection with the first, second and third aspects.

The nanoparticles may have a surface energy between about 20 and 60 J/m³, and the device may comprise multiple nanoparticle layers, for example two, three, four, five or more layers. In one embodiment, the device comprises five nanoparticle layers. The device may be an electronic device, for example an LED, a transistor or a photovoltaic cell. The nanoparticles may be core shell nanoparticles, and in one embodiment comprise the conductive organic polymer compounds PFB and F8BT. The nanoparticles may have a surface energy between about 30 and about 40 J/m³, or about 38 J/m³. The nanoparticles may have a mean diameter of about 50 nm and a domain size between about 20 nm and 25 nm.

The device of the sixth aspect may be prepared by the processes described and exemplified herein.

### EXAMPLES

The invention will now be described in more detail, by way of illustration only, with respect to the following example. The example is intended to serve to illustrate this invention and should in no way be construed as limiting the generality of the disclosure of the description throughout this specification.

### Preparation of a Device Based on PFB:F8BT Nanoparticles

Described below is a process for preparing a photovoltaic device in accordance with one embodiment of the invention.

### Preparation of Nanoparticles

Semi-conducting polymeric nanoparticles were prepared as outlined by Landfester and co-workers (Nat. Mater., 2, 408 (2003). F8BT and PFB (American Dye Source Inc) in the ratio of 1:1 by weight (30 mg total) were first dissolved in chloroform (0.8 g) and then introduced to an aqueous SDS solution (Sigma-Aldrich >99.8% purity, 52 mM, 2.8 mL MilliQ water). The solution was stirred at 1200 rpm for 1 hour to form a macroemulsion. The emulsion was then sonicated using a Branson 450 analogue sonifier for 2 mins at 60% amplitude with a microtip (radius 6.5 mm) immersed in the emulsion. After sonication the miniemulsion samples were heated at 60° C. for 3 hours whilst continually stirring at 1200 rpm to evaporate off the chloroform leaving a stable aqueous suspension of polymer nanoparticles.

Dialysis of the nanoparticle suspensions was performed to concentrate the samples and remove excess surfactant from the suspension. Dialysis was performed using ultra centrifuge dialysis tubes purchased from Millipore (10 kDa MWCO). Dispersions produced via the miniemulsion process were placed into a centrifuge dialysis tube and spun at 4000 rpm for 6 minutes. The filtrate was then discarded and the nanoparticle suspension diluted with MilliQ water (2 mL). The tube was sealed and then spun for 7 minutes at 4000 rpm. This process was repeated until the surface tension of the filtrate reached 38±2 mN/m. The dispersions were still colloidally stable after 3 months.

### Nanoparticle Characterisation

A Zetasizer Nano-ZS (Malvern Instruments, UK) equipped with a helium-neon laser source (wavelength 633 nm; power 4.0 mW) was used for measuring the hydrodynamic diameter of the dialysed semiconducting polymer colloids produced. Each sample was measured 5 times and the z-average was recorded.

Transmission electron microscopy (TEM) was performed on A JEOL JEM-1200EXII TEM (1992) and digital imaging (2007) software was used at a working voltage of 80 kV. The nanoparticles were dip-coated from the dialysed aqueous dispersions directly onto carbon-backed copper TEM grids and air dried to yield clusters of particles on an amorphous carbon film.

Differential scanning calonmetry (DSC) was performed on a Shimadzu DSC-60A instrument used in conjunction with a Shimadzu TA-60WS thermal analyser. Samples of 2 to 5 mg were prepared by drop casting the dialysed solutions into the aluminium sample plan and leaving in a laminar flow cabinet overnight to dry. The temperature cycling experiment with increasing maximum temperature was designed to identify reversible and irreversible thermal transitions within the sample under investigation. The ramp and cooling rate used throughout was 10° C. min⁻¹.

The atomic force microscope (AFM) used in this study was a Nanoscope IIIE instrument (Digital Instruments/Veeco Metrology group CA) operated in contact mode using NP cantilevers of spring constant 0.06 N m⁻¹.

A Dataphysics OCA 20 (Germany) instrument was used to measure contact angles of sessile drops of the nanoparticle dispersions on spin cast nanoparticle monolayers in order to investigate the spreading and wetting characteristics of the dispersions.

XRR measurements were performed at the Australian Nuclear Science and Technology Organisation (ANSTO), Sydney, Australia. Angular dispersive measurements were conducted in air using an X'pert PRO PW3040/60 X-ray Reflectometer (PANanalytical) emitting Cu Kα X-rays (wavelength=1.5418 Å) produced from a 45 kV tube source, focused using a Göbel mirror and collimated with 0.2 mm pre and post-sample slits. The intensity of reflected X-rays was recorded using a NaI scintillation detector. The specular x-ray reflectivity, R, (the ratio between the reflected and the incident intensity) was measured over the Q-range 0.01 Å⁻¹<Q<0.4 Å⁻¹, where Q=4 πsinθ/λ is the momentum transfer and θ is the angle of incidence/reflection.

### Device Fabrication

PEDOT:PSS (Baytron P) films were spin-coated (5000 rpm) on pre-cleaned patterned ITO glass slides and annealed at 140° C. for 30 min to eliminate water in the films. PFB:F8BT nanoparticle layers were deposited by spin coating 35 μl of the dispersion (2000 rpth for 1 minute) in air. Following the deposition of each layer, the film was dried at 70° C. for 15 min. For the final layer, the film drying takes place at 140° C. for 15 min and the films were then transferred into a vacuum chamber for electrode evaporation. The aluminium (Al) electrodes were evaporated on the active layers in vacuum (2×10⁻⁶ Torr). The thickness of the Al layer was measured to be about 70 nm using a quartz crystal monitor and the area of each cell was 5 mm². After evaporation, fabricated devices were tested and then annealed at 140° C. on a hot plate (temperature variation ±2° C.) for 4 min under a nitrogen atmosphere and then tested again.

### Device Characterisation

For the UV-Vis and XRD characterization, the relevant films were spin coated on normal silica glass slides. An ultraviolet-visible absorption spectrophotometer (UV-Vis, Varian Cary 6000i) was used to study the absorption of PFB-F8BT nanoparticulate and blend films. For these measurements the evaporation of the metal electrode was omitted.

The photocurrent density-voltage (J-V) measurements were conducted using a Newport Class A solar simulator with an AM 1.5 spectrum filter to illuminate the full cells. The light intensity was measured to be 100 mW cm⁻² by a silicon reference solar cell (FHG-ISE) and the J-V data were recorded by a Keithley 2400 source meter.

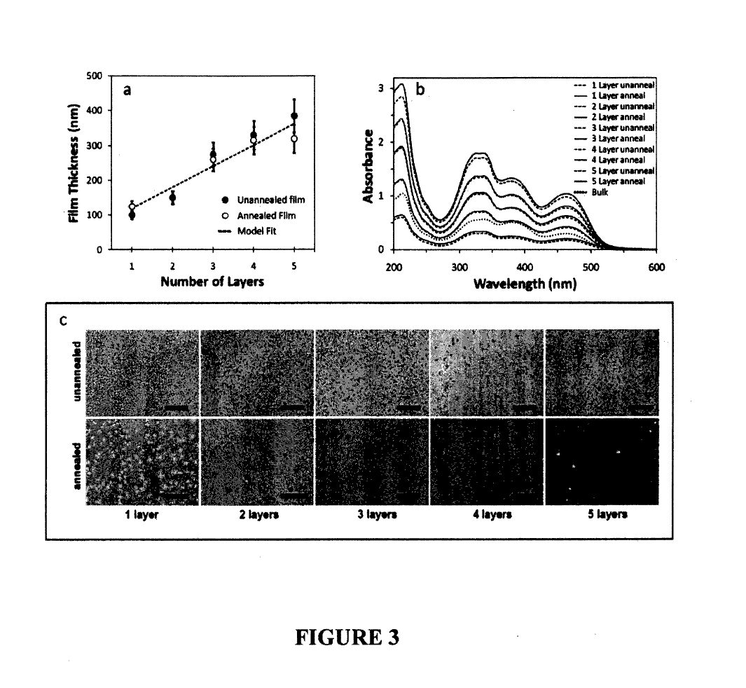

STXM measurements were performed at the Advanced Light Source on beamline 5.3.2 (J. Synchrotron Radiat., 10, 125 (2003). The SiN window mounted sample is rastered with respect to the X-ray beam in helium (0.33 atm) with the transmitted X-ray signal detected by a scintillator and a photomultiplier tube. The energy of the X-ray beam was varied between 250 and 340 eV, which covered the C K-edge with a resolution of 100 meV. The component maps in FIG. 3 are derived by the following process. Lateral drifting between images at different energies were corrected by shifting the images laterally to achieve a maximum in the image correlation function. The NEXAFS spectra of the pristine PFB, F8BT and SDS spectra were background corrected by dividing the signal intensity at each energy by the corresponding intensity through a clean SiN window. The spectra were then converted to optical density. At each pixel in the STXM image a three point spectra was obtained and a singular value decomposition algorithm (constrained to positive solutions) was used to fit a sum of the three pristine spectra to the measured blend spectra. The resulting coefficients are indicative of the masses of each of the three components present at that pixel and dividing each of the images by the summed image gives an indication of the percentage composition of each component. These calculations are performed at each pixel, resulting in composition maps. The composition maps have been filtered with a low pass FFT filter. Further details of expenment and data analysis can be found elsewhere (Nano Lett., 6,1202 (2003). Image analysis was assisted by use of the IDL widget aXis2000 (http://unicorn.mcmaster.ca/aXis2000.html).

### Results and Discussion

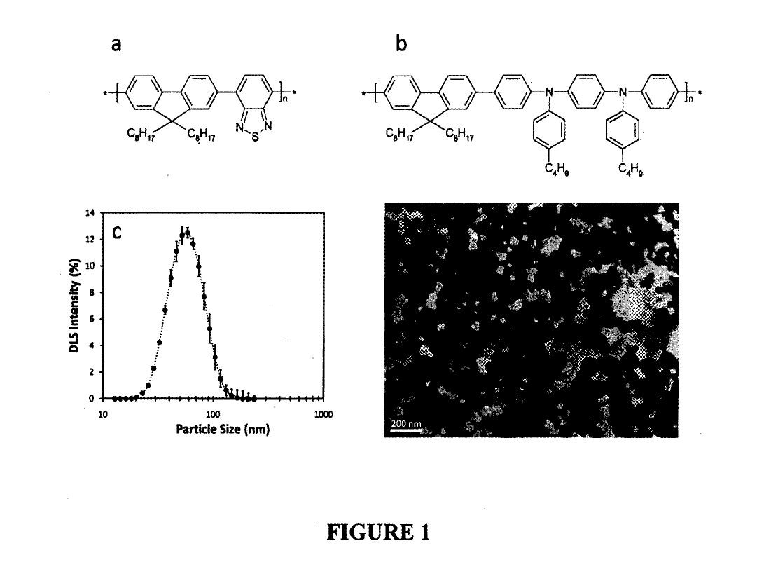

FIG. 1 shows a transmission electron micrograph of the blended particles used to prepare the exemplified device. It is noted that distinct spherical particles are produced. Dynamic light scattering (DLS) was used to measure the distribution of particle sizes in the aqueous solution (FIG. 1 inset). The mean z-average particle size was found to be 51.9±1.3 nm.

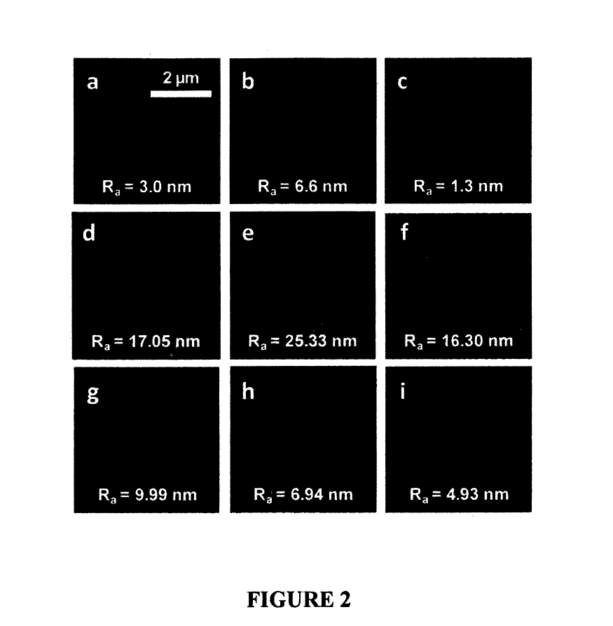

FIG. 2 shows sequential atomic force micrographs of the device surface with each deposited layer in the multilayered structure. The AFM images show that each individual layer is relatively smooth with little evidence of particle agglomeration during the deposition process. Importantly, the surface roughness steadily decreases with sequential layer deposition, indicating that the particles are deposited in any vacancies or depressions that might be present in the underlying film to give an increasingly smooth surface with a close packed active layer structure. Recent work by Farr and Groot has shown how the close packing of polydisperse spheres in a viscous medium depends not only on solvent viscosity but also on particle size distribution, with higher polydispersity resulting in higher packing fractions (J. Chem. Phys. 131, 244104 (2009)). Thus, the fabrication of multilayered device architectures requires careful control of the particle size distribution in the aqueous dispersion (FIG. 1) to ensure the production of close-packed layers. Further active layer smoothing occurs upon annealing the films at 140° C., which occurs for both the PEDOT:PSS substrate layer and the final multilayered PFB:F8BT device.

Further evidence that the device active layer is built up in a stepwise manner is provided from profilometry data of the cumulative film thickness measured at each fabrication step. Using a simple model for the spherical close packing of monodisperse particles it is possible to show that, for a particle radius, r, the thickness, d, of the nth layer is given by the following equation:

d=d_{PEDOT}+2r+\sqrt{3}(n−1)r

As shown in FIG. 3a (and Table 1 below), there is very good agreement between the measured thickness of the layers and the predicted model thickness, indicating that the layer is built up from sequential close packed monolayers. In general, for structures consisting of more than two particulate layers, annealing results in slightly lower structures, suggesting some rearrangement of the films takes place upon annealing.

FIG. 3b shows the UV-Vis spectra for the exemplified PFB-F8BT multilayered device at each stage of the fabrication process and indicates that the UV-Vis absorbance increases systematically with every deposited layer. In addition, FIG. 3b shows that the absorbance of the annealed films is slightly higher than that of the unannealed films, despite the fact that the annealed films are slightly thinner than the unannealed films. Optical microscopy of the multilayered films (FIG. 3c) indicates that smoother films are formed upon annealing, with evidence for the presence of approximately micron-sized features upon the surface of (or embedded within) the unannealed films. As such, the increased UV-Vis absorbance of the annealed films is consistent with decreased scattering from the film surface and hence all of the physical and spectroscopic studies are consistent with the fabrication of PFB-F8BT multi-layered structures consisting of close packed arrays of particles.

The characteristics of photovoltaic devices fabricated from the multilayered structures are shown in Table 1. The most efficient devices are produced from the five layer devices, which exhibit a power conversion efficiency (PCE) under AM 1.5 illumination of 0.39%. EQE spectra for five layer nanoparticulate devices exhibit quantum efficiencies similar to those obtained for bulk PFB:F8BT blends (J. Phys. Chem. C, 111, 19153 (2007)) and indicate that both polymers are contributing equally to the total photocurrent generated by the devices. The measured power conversion efficiency reported here are significantly higher than those previously reported for devices fabricated from aqueous dispersions of nanoparticles.

TABLE 1
Comparison of device characteristics for PFB:F8BT multilayered
structures at each fabrication step. Also shown is data for a 120 nm
thick bulk heterojunction device fabricated from a 1:1 blend of PFB
and F8BT in chloroform. The numbers in parentheses refer to
the unannealed device data.

| | | J_{sc} | | | | | |
|---|---|---|---|---|---|---|---|
| | V_{oc} | (mA/ | | PCE | Rₛ | Rₛₕ | Rₛₕ/ |
| Layers | (V) | cm²) | FF | (%) | (kΩ) | (kΩ) | Rₛ |
| 1 | 0.43 | 0.30 | 0.28 | 0.04 | 13.9 | 52.5 | 3.8 |
| 2 | 0.84 | 0.44 | 0.27 | 0.10 | 32.2 | 59.7 | 1.9 |
| 3 | 0.89 | 0.46 | 0.26 | 0.10 | 44.8 | 46.9 | 1.0 |
| 4 | 0.48 | 1.02 | 0.26 | 0.13 | 8.7 | 10.2 | 1.2 |
| 5 | 0.77 | 1.81 | 0.28 | 0.39 | 2.0 | 18.1 | 9.3 |
| | (0.37) | (0.16) | (0.26) | (0.02) | (53.5) | (78.9) | (1.5) |
| 6 | 0.50 | 0.51 | 0.28 | 0.06 | 29.8 | 56.0 | 1.9 |
| 7 | 0.22 | 0.27 | 0.25 | 0.01 | 12.6 | 18.5 | 1.5 |
| 8 | 0.88 | 0.38 | 0.33 | 0.09 | 20.2 | 73.5 | 3.6 |
| Bulk | 1.09 | 0.70 | 0.27 | 0.20 | 9.8 | 30.0 | 3.1 |
| | (1.16) | (0.63) | (0.25) | (0.18) | (56.6) | (71.6) | (1.3) |

The only previous measurement of the performance of PFB:F8BT nanoparticle devices under solar illumination was that of Kietzke et al. who reported devices with a J_{sc}=1×10⁻⁵ A cm⁻² and V_{oc}=1.38V (Macromolecules, 37, 4882 (2004)), which (assuming a best estimate unannealed fill factor of 0.28 from bulk blend devices (J. Phys. Chem. C, 111, 19153 (2007)) corresponds to a PCE of 0.0039%. The only other photovoltaic measurements of PFB:F8BT nanoparticle devices have been the plots of external quantum efficiency (EQE) reported by both Kietzke et al. (Nat. Mater., 2, 408 (2003)) and Snaith et al. (Synth. Met., 147, 105 (2004)).

It is possible to estimate the PCE from EQE data by convoluting the EQE and AM1.5 spectra and then integrating, which gives a PCE of 0.056% (using the highest reported EQE data for PFB:F8BT 1:2 nanoparticulate films (Macromolecules, 37, 4882, (2004)) and assuming a best estimate fill factor of 0.28 from bulk blend devices (J. Phys. Chem. C, 111, 19153 (2007)). Given that Moule has shown that the EQE of P3HT:PCBM devices increases with decreasing light intensity, this result is likely to be an overestimate of the PCE since the light intensity of the EQE measurement is much lower than under AM1.5 conditions (Appl. Phys B 92, 209 (2008)). As such, the optimized device efficiency of the exemplified device is between one and two orders of magnitude higher than has been reported previously. Remarkably, the efficiency of the nanoparticle multilayered device is also twice as efficient as the best bulk PFB:F8BT heterojunction device (see Table 1).

The possibility that this increased efficiency arises from the greater thickness of the nanoparticle multilayered device can be discounted since measurements of the efficiency of bulk PFB:F8BT heterojunction devices show no dependency upon device thickness in this thickness range. While there is some evidence of stress-induced cracking of the thicker films, AFM data show that these cracks do not penetrate all the way through and thus, in general, thicker films result in a more continuous particulate layer. As such, the addition each subsequent layer in these devices acts to repair and remove defect sites in the nanoparticulate film, resulting in the observed improved efficiency.

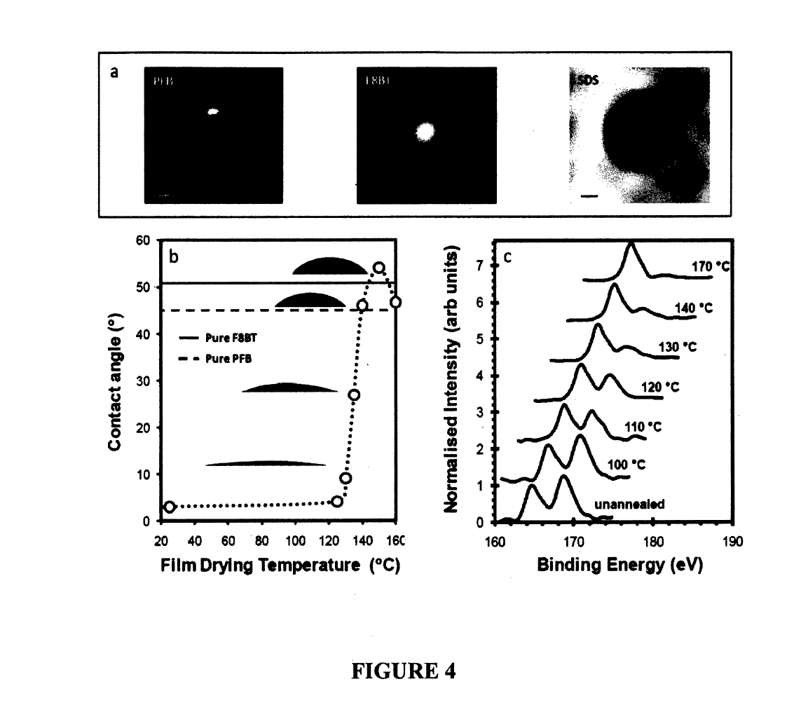

STXM maps of the PFB, F8BT and SDS compositions for a single unannealed PFB:F8BT nanoparticle are shown in FIG. 4a and indicate that the unannealed particles are surrounded by a shell of SDS material, which acts to sterically stabilise the aqueous dispersions and enable the colloidal particles to be used for up to 3 months after dialysis. The apparent thickness of the shell is of the order of 10 nm, which although is much larger than the length of the SDS molecule (1.9 nm, J. Phys. Chem B. 113, 1303 (2009)) arises from the fact that the STXM image is a transmission image and thus the measured composition is related to the integrated density of SDS molecules through the nanoparticle. More importantly, the STXM maps show clear evidence of a core-shell structure with PFB-rich and F8BT-rich domains concentrated on the outside and at the centre of the nanoparticle respectively. This distribution of PFB and F8BT is consistent with the known relative surface energies of the two polymers and with the contact angle measurements presented in FIG. 4b which show that PFB has a lower surface energy (in contact with water) than F8BT and thus should phase segregate to the aqueous interface of the particle during fabrication. However, this observation contrasts with the Janus structure proposed by Kietzke et al. on the basis of TEM studies of biphasic polystyrene/poly(propylene carbonate) particles (Small, 3, 1041 (2007)).

FIG. 4b also shows that the surface energy of the PFB/F8BT nanoparticle film changes significantly at annealing temperatures near 140° C. At this temperature the surface becomes much more hydrophobic and exhibits a contact angle value comparable to that of the pure polyfluorenes. As such, the previously embedded surfactant must no longer be present at the surface of the annealed particle film and it is presumed that at the annealing temperature the polymer components of the polyfluorene blend are sufficiently mobile so as to diffuse to the surface of the nanoparticle film.

This model of the particle monolayer is supported by the XPS S 2p spectra of the films following annealing at temperatures from 100° C. to 170° C. (FIG. 4c). The spectra consist of two doublets, a lower energy doublet arising from the S 2p signal from F8BT and a higher energy doublet arising from the S 2p signal from SDS (Langmuir, 15, 2566 (1999)). The intensity of the SDS signal decreases systematically relative to that of the F8BT signal with increasing annealing temperature, and effectively vanishes for temperatures above 140° C. Thus, upon annealing, SDS is lost from the surface of the film resulting in the observed change in contact angle.

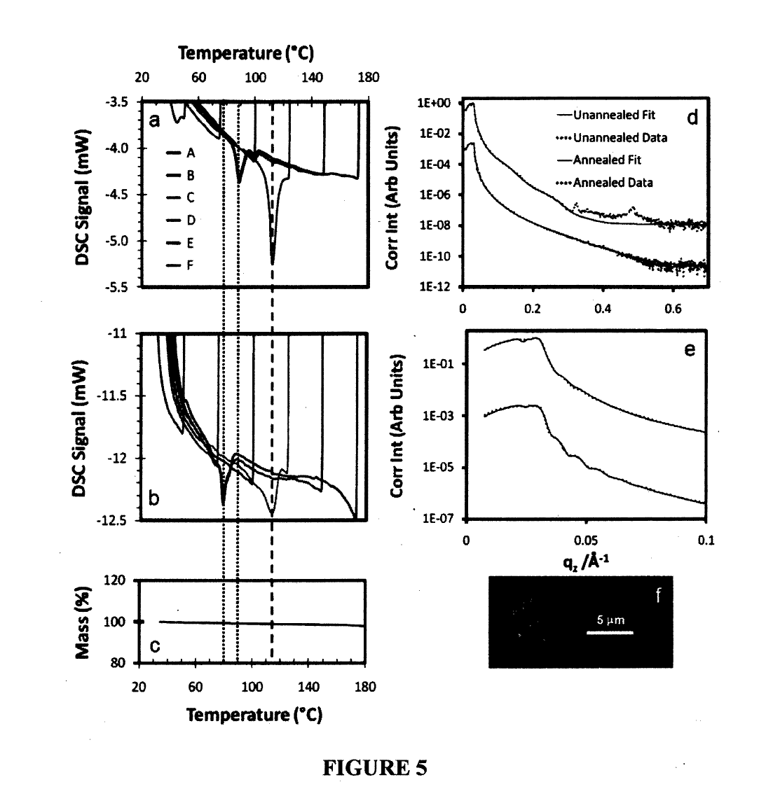

FIGS. 5a and 5b show the DSC data for pure SDS with that for PFB:F8BT nanoparticles for a sequence of temperature ramps. A comparison of the data shows that the response at 110° C. in the DSC signal for PFB:F8BT nanoparticles arises from an exothermic transition of the SDS molecules that occurs just below the annealing temperature and is characteristic of the known “chain-melting” transition from a crystalline phase to a disordered phase in dehydrated SDS (Journal of Colloid and Interface Science, 131, 112 (1989)). Once this phase transition has occurred, a reversible DSC response then appears at −80° C. for the nanoparticles and ˜90° C. for the pure SDS. These temperatures correspond to a complex region of the SDS phase diagram where high purity SDS is converted between lamellar and crystalline phases (Journal of Colloid and Interface Science, 131, 112 (1989). Moreover, TGA analysis (FIG. 5c) shows no evidence of any mass loss of the particles. As such, the DSC data is consistent with the irreversible loss of crystalline SDS from the nanoparticulate film surface and the formation of a less ordered SDS phase within the bulk film.

FIG. 5d shows the X-ray reflectometry (XRR) data for a monolayer of unannealed and annealed PFB:F8BT nanoparticle films. The layer thicknesses measured from the low q_{z} oscillation period (FIG. 5e) are 74.5 nm and 62.6 nm for the unannealed and annealed nanoparticulate films respectively and are in good agreement with those obtained by profilometry and confirm the earlier observation that the film thickness decreases slightly upon annealing. The key feature of the XRR data is the observation of a broad feature superposed with sharper diffraction peaks in the unannealed sample that vanish upon annealing. The position of these diffraction peaks indicates a vertical lattice spacing of 3.9 nm, which corresponds to the known unit cell distance of crystalline SDS (Journal of Colloid and Interface Science, 131, 112 (1989)). Indeed, AFM data (FIG. 5f) and the optical microscopy data (FIG. 2c) suggest the presence of isolated SDS crystallites on the unannealed nanoparticulate film surface. Although AFM indicates that some crystallites are still present on the post-annealed film surface, the loss of diffraction peaks in the XRR data coupled with the change in contact angle demonstrates that SDS is overwhelmingly lost from the surface upon annealing. In addition, both the XRR and DSC data indicate that the polymer phase is pnmarily amorphous. This suggests a model for the unannealed film consisting of amorphous polymer nanoparticles surrounded by SDS and with crystallites of free SDS on the film surface. Upon annealing, the SDS undergoes chain-melting, becomes mobile and is lost from the film surface.

### CONCLUSION

Devices have been fabricated from polymer nanoparticles and have demonstrated the highest power conversion efficiencies yet observed for these materials. This high performance is made possible through control of the surface energies of the individual components in the polymer nanoparticle and the post-deposition processing of the polymer nanoparticle layers. In particular, it has been shown that with careful annealing, the surfactant layer is removed from the outermost surface of the polymer nanoparticle thus providing an unhindered pathway for inter-particle charge transport. In contrast with previous work, it has been demonstrated that it is possible to fabricate nanoparticle OPV devices that are more efficient than the standard blend devices. This improvement is achieved through: (I) successful migration of surfactant away from the particle interface, (2) creation of core-shell nanoparticles with a composition that enables effective electron and hole transport, and (3) optimization of polymer domain size to maximize both charge separation and transport. The results demonstrate that the nanoparticle approach provides a level of control over the nanomorphology of the device that is simply not achievable by simple blending of bulk materials.

Those skilled in the art will appreciate that the invention described herein is susceptible to variations and modifications other than those specifically described. It is to be understood that the invention includes all such variations and modifications.

1. A process for preparing a device comprising:
(i) providing an aqueous emulsion comprising an organic solvent, a surfactant and at least one conductive organic compound;
(ii) removal of the organic solvent to provide an aqueous suspension of conductive nanoparticles comprising the at least one conductive organic compound;
(iii) depositing the nanoparticles onto a substrate to form a nanoparticle layer; and
(iv) annealing the nanoparticle layer.

2. The process of claim 1, further comprising dialysis of the aqueous suspension of nanoparticles so as to minimise the amount of surfactant therein;

3. The process of claim 2, wherein dialysis is performed until the surface tension of a filtrate is less than about 50 mN/m.

4. The process of any one of claims 1 to 3, wherein the nanoparticles have a mean diameter between about 5 nm and about 200 nm and a mean domain size between about 2 nm and about 110 nm.

5. The process of claim 4, wherein the nanoparticles have a mean diameter between about 45 nm and about 60 nm and a mean domain size between about 15 nm and about 30 nm.

6. The process of any one of claims 1 to 5, wherein step (iii) is repeated so as to provide multiple nanoparticle layers.

7. The process of claim 6, wherein step (iii) is repeated two, three or four times.

8. The process of claim 7, wherein step (iii) is repeated four times.

9. The process of any one of claims 6 to 8, wherein following step (iii) and each repetition thereof, the nanoparticle layer is dried.

10. The process of claim 9, wherein following step (iii) and each repetition thereof, the nanoparticle layer is dried at a temperature between about 50° C. and 150° C.

11. The process of any one of claims 1 to 10, wherein step (iv) is performed by heating the nanoparticle layer(s).

12. The process of claim 11, wherein the nanoparticle layer(s) are heated at a temperature between about 130° C. and 150° C.

13. The process of any one of claims 1 to 12, wherein the nanoparticles comprise at least one conductive organic compound selected from the group consisting of:
porphyrins, phthalocyanins, polyacetylenes, fullerenes, polyparaphenylenes, polyphenylenevinylenes, polyfluorenes, polythiophenes, polypyrroles, polypyridines, polycarbazoles, polypyridinevinylenes, polyarylvinylenes and poly (p-phenylmethylvinylenes), including derivatives and co-polymers thereof.

14. The process of claim 13, wherein the nanoparticles comprise at least one conductive organic compound selected from the group consisting of poly(9,9-dioctylfluorene-2,7-diyl-co-bis-N,N-(4-butylphenyl)-bis-N,N-phenyl-1,4-phenylenediamine), poly(9,9-dioctylfluorene-2,7-diyl-co-benzothiadiazole), poly-3-hexylthiophene, (6,6)-phenyl-C₆₁-butyric acid methyl ester and poly(2-methoxy-5-(2’-ethyl-hexyloxy)-1,4-phenylene vinylene).

15. The process of claim 14, wherein the nanoparticles comprise the following conductive organic compounds: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

16. The process of any one of claims 1 to 12, wherein the at least one conductive organic compound is a conductive organic polymer compound.

17. The process of any one of claims 1 to 16, wherein the device is an electronic device.

18. A process for preparing a film or device comprising conductive nanoparticles, the process including the step of preparing conductive nanoparticles having a mean diameter between about 5 nm and about 200 nm, and a mean domain size between about 2 nm and about 110 nm.

19. The process of claim 18, wherein the nanoparticles have a mean diameter between about 45 nm and about 60 nm and a mean domain size between about 15 nm and about 30 nm.

20. The process of claim 18 or claim 19, wherein the conductive nanoparticles are conductive polymer nanoparticles.

21. The process of claim 20, wherein the conductive polymer nanoparticles comprise: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

22. A process for preparing a film or device comprising conductive nanoparticles, said process including the step of modulating the surface energy of the nanoparticles.

23. The process of claim 22, wherein modulating the surface energy of the nanoparticles is achieved by dialysis of an aqueous dispersion comprising the nanoparticles and a surfactant so as to minimise the amount of surfactant therein, and annealing of the nanoparticles once deposited as a nanoparticle layer on a substrate.

24. A process for preparing a film or device comprising conductive nanoparticles, the process including the step of removing surfactant located at the surface of the nanoparticles.

25. The process of any one of claims 22 to 24, wherein the conductive polymer nanoparticles comprise: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

26. A device comprising at least one nanoparticle layer, the nanoparticles comprising at least one conductive organic compound and having a mean diameter between about 5 nm and 200 nm and a mean domain size between about 2 nm and 110 nm wherein the surface of the nanoparticles is free, or substantially free, of surfactant.

27. The device according to claim 26, wherein the nanoparticles have a mean diameter between about 45 nm and 60 nm and a mean domain size between about 15 nm and 30 nm

28. The device of claim 26 or claim 27, wherein the nanoparticles comprise at least one conductive organic polymer compound.

29. The device of any one of claims 26 to 28, wherein the nanoparticles comprise: poly(9,9-dioctylfluorene-2,7-diyl-co-bis-N,N-(4-butylphenyl)-bis-N,N-phenyl-1,4-phenylenediamine) and poly(9,9-dioctylfluorene-2,7-diyl-co-benzothiadiazole).

30. The device of any one of claims 26 to 29, wherein the nanoparticles have a surface energy between about 30 and about 40 J/m³.

31. The device of any one of claims 26 to 30, wherein the device comprises five nanoparticle layers.

32. The device of any one of claims 26 to 31, which is an electronic device.
